(19) United States
(12) Patent Application Publication
(10) Pub. No.: US 2019/0296138 A1
(43) Pub. Date: Sep. 26, 2019

(54) SEMICONDUCTOR APPARATUS AND MANUFACTURING METHOD THEREOF

(71) Applicants: Kabushiki Kaisha Toshiba, Tokyo (JP); Toshiba Electronic Devices & Storage Corporation, Tokyo (JP)

(72) Inventors: Hiroaki HAYASHI, Nonoichi Ishikawa (JP); Seiji INUMIYA, Kanazawa Ishikawa (JP); Takashi ONIZAWA, Nomi Ishikawa (JP); Emiko INOUE, Nonoichi Ishikawa (JP)

(73) Assignees: Kabushiki Kaisha Toshiba, Tokyo (JP); Toshiba Electronic Devices & Storage Corporation, Tokyo (JP)

(21) Appl. No.: 16/120,042

(22) Filed: Aug. 31, 2018

(30) Foreign Application Priority Data
Mar. 22, 2018 (JP) 2018-055382

(51) Int. Cl. H01L 29/778; H01L 29/10; H01L 29/20; H01L 29/66; H01L 21/306; H01L 21/3065

(52) U.S. Cl. CPC H01L 29/7786; H01L 29/1037; H01L 21/3065; H01L 29/66462; H01L 21/30604; H01L 29/2003

(57) ABSTRACT

A semiconductor apparatus according to the present embodiment is a semiconductor apparatus including a first nitride semiconductor layer including a first region having a first upper surface, a second region having a second upper surface parallel to the first upper surface, and a third region provided between the first region and the second region and having a third upper surface inclined with respect to the first upper surface and the second upper surface; a second nitride semiconductor layer including a fourth upper surface provided above the first upper surface, a fifth upper surface provided above the second upper surface, and a sixth upper surface provided above the third upper surface and being parallel to the third upper surface, the fourth upper surface being parallel to the first upper surface and being a +c face, the fifth upper surface parallel to the second upper surface and being a +c face, and the second nitride semiconductor having a bandgap larger than that of the first nitride semiconductor layer; a source electrode provided on the fourth upper surface; a drain electrode provided on the fifth upper surface; a gate electrode provided on the sixth upper surface; and a gate insulating film provided between the sixth upper surface and the gate electrode.

### CROSS-REFERENCE TO RELATED APPLICATION

This application is based upon and claims tho benefit of priority from Japanese Patent Application No. 2018-055382, filed on Mar. 22, 2018, the entire contents of which are incorporated herein by reference.

### FIELD

Embodiments described herein relate generally to a semiconductor apparatus and a manufacturing method thereof.

### BACKGROUND

Attention has been paid to a nitride semiconductor typified by group III nitride such as gallium nitride (GaN) as a material for the next generation power semiconductor device. The nitride semiconductor has a bandgap larger than that of silicon (Si). For this reason, a nitride semiconductor device can realize a small and high breakdown voltage power semiconductor device, as compared with a silicon (Si) semiconductor device. In addition, since parasitic capacitance can be reduced in this way, a high speed driven power semiconductor device can be realized.

In a transistor using the nitride semiconductor, a high electron mobility transistor (HEMT) structure in which a plurality of nitride semiconductor layers having different bandgaps are combined with one another and a two dimensional electron gas (2DEG) is used as a carrier is generally used. A normal HEMT is a normally-on transistor that conducts even if a voltage is not applied to a gate thereof. For this reason, there is a problem that it is difficult to realize a normally-off transistor that does not conduct unless a voltage is applied to a gate thereof. Therefore, a transistor having a structure capable of realizing a normally-off operation while utilizing high electron mobility possessed by the 2DEG has been demanded.

### BRIEF DESCRIPTION OF THE DRAWINGS

FIG. 1 is a schematic cross-sectional view of a semiconductor apparatus according to a first embodiment;

FIGS. 2A and 2B are schematic diagrams for describing crystal structures and face orientations of a nitride semiconductor;

FIGS. 3A and 3B are schematic diagrams for describing crystal structures and face orientations of a nitride semiconductor;

FIGS. 4A and 4B are schematic cross-sectional views showing some of manufacturing processes in a manufacturing method of the semiconductor apparatus according to the first embodiment;

FIGS. 5A and 5B are schematic diagrams showing a band structure formed by a first nitride semiconductor layer and a second nitride semiconductor layer in a description of a function and an effect according to the first embodiment;

FIG. 6 is a schematic cross-sectional view of a semiconductor apparatus according to a second embodiment;

FIGS. 7A to 7C are schematic cross-sectional views showing some of manufacturing processes in a manufacturing method of the semiconductor apparatus according to the second embodiment;

FIG. 8 is a schematic cross-sectional view of a semiconductor apparatus according to a third embodiment;

FIG. 9 is a schematic cross-sectional view of a semiconductor apparatus according to a fourth embodiment;

FIGS. 10A to 10C are schematic cross-sectional views showing some of manufacturing processes in a manufacturing method of the semiconductor apparatus according to the fourth embodiment;

FIGS. 11A to 11C are schematic cross-sectional views showing some of manufacturing processes in a modified example of a manufacturing method of the semiconductor apparatus according to the fourth embodiment;

FIG. 12 is a schematic cross-sectional view of a semiconductor apparatus according to a fifth embodiment;

FIG. 13 is a schematic cross-sectional view of a semiconductor apparatus according to a sixth embodiment;

FIGS. 14A to 14C are schematic cross-sectional views showing some of manufacturing processes in a manufacturing method of the semiconductor apparatus according to the sixth embodiment;

FIGS. 15A to 15C are schematic cross-sectional views showing some of manufacturing processes in a modified example of a manufacturing method of the semiconductor apparatus according to the sixth embodiment; and

FIG. 16 is a schematic cross-sectional view of a semiconductor apparatus according to a seventh embodiment.

### DETAILED DESCRIPTION

Hereinafter, embodiments will be described with reference to the drawings. It should be noted that the same or similar components are denoted by the same or similar reference numerals in the drawings.

In the present specification, the same or similar members are denoted by the same reference numerals, and an overlapping description may be omitted.

In the present specification, a “nitride (GaN-based) semiconductor” generally refers to a semiconductor having gallium nitride (GaN), aluminum nitride (AlN), indium nitride (InN), and their intermediate compositions.

In the present specification, “undoped” means that an impurity concentration is 1×10¹⁵ cm⁻³ or less.

In the present specification, in order to indicate a position relationship between components, and the like, a top direction of the drawings is described as “top” and a bottom direction of the drawings is described as “bottom”. In the present specification, concepts of the “top” and the “bottom” are not necessarily terms indicating a relationship with a direction of gravity.

In addition, in the present specification, “contact” or “contacting” includes a case where two components are in direct contact with each other and a case in which two components are in indirect contact with each other through a modified layer, an intermediate layer, an insulating film, or the like.

### First Embodiment

A semiconductor apparatus according to the present embodiment is a semiconductor apparatus including a first nitride semiconductor layer including a first region having a first upper surface, a second region having a second upper surface parallel to the first upper surface, and a third region provided between the first region and the second region and having a third upper surface inclined with respect to the first upper surface and the second upper surface; a second nitride semiconductor layer including a fourth upper surface provided above the first upper surface, a fifth upper surface provided above the second upper surface, and a sixth upper surface provided above the third upper surface and being parallel to the third upper surface, the fourth upper surface being parallel to the first upper surface and being a +c face, the fifth upper surface parallel to the second upper surface and being a +c face, and the second nitride semiconductor having a bandgap larger than that of the first nitride semiconductor layer; a source electrode provided on the fourth upper surface; a drain electrode provided on the fifth upper surface; a gate electrode provided on the sixth upper surface; and a gate insulating film provided between the sixth upper surface and the gate electrode.

In addition, a semiconductor apparatus according to the present embodiment is a semiconductor apparatus including a first nitride semiconductor layer including a first region having a first upper surface, a second region having a second upper surface parallel to the first upper surface, and a third region provided between the first region and the second region and having a third upper surface inclined at an angle of 88° to 90° with respect to the first upper surface or the second upper surface; a second nitride semiconductor layer provided on the first nitride semiconductor layer, the second nitride semiconductor including a fourth upper surface provided above the first upper surface, a fifth upper surface provided above the second upper surface and a sixth upper surface parallel to the third upper surface, the fourth upper surface being parallel to the first upper surface and being a +c face, the fifth upper surface being parallel to the second upper surface and being a +c face and the second nitride semiconductor layer having a bandgap larger than that of the first nitride semiconductor layer; a source electrode provided on the fourth upper surface; a drain electrode provided on the fifth upper surface; a gate insulating film provided to be in contact with the sixth upper surface; and a gate electrode provided to be in contact with the gate insulating film.

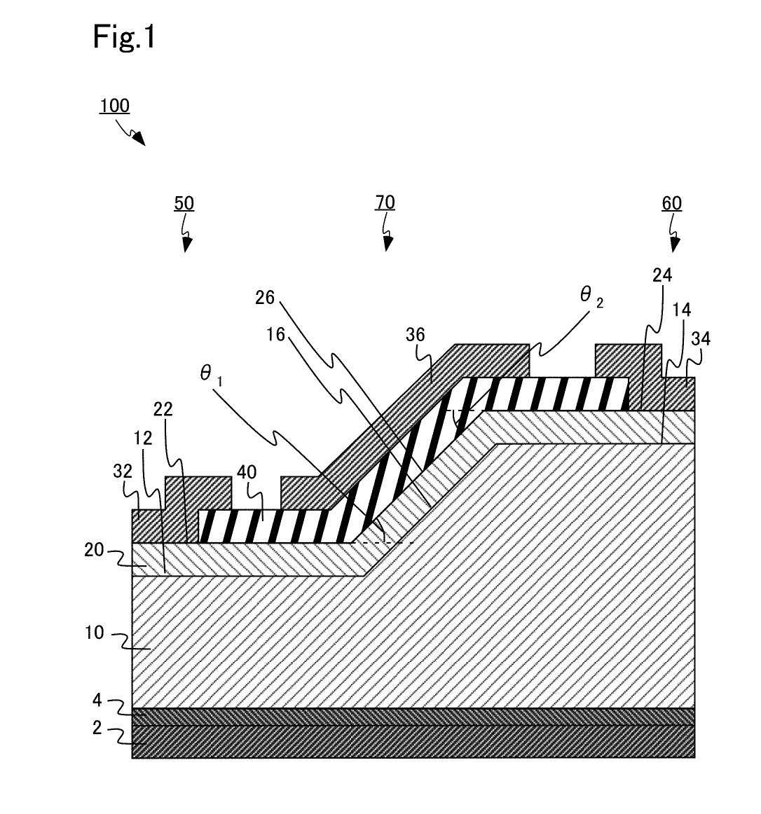

FIG. 1 is a schematic cross-sectional view of a semiconductor apparatus 100 according to the present embodiment.

The semiconductor apparatus 100 includes a substrate 2, a buffer layer 4, a first nitride semiconductor layer 10, a second nitride semiconductor layer 20, a source electrode 32, a drain electrode 34, a gate electrode 36, and a gate insulating film 40.

The first nitride semiconductor layer 10 has a first upper surface 12, a second upper surface 14, and a third upper surface 16.

The second nitride semiconductor layer 20 has a fourth upper surface 22, a fifth upper surface 24, and a sixth upper surface 26.

The substrate 2 is, for example, a semiconductor substrate. For example, a semiconductor substrate containing a p-type impurity or an n-type impurity and having a low resistance value is preferably used as the substrate 2. Specifically, a silicon (Si) substrate, a silicon carbide (SiC) substrate, a sapphire substrate, and the like, are preferably used as the substrate 2.

The first nitride semiconductor layer 10 is formed of, for example, undoped AlₓGa₁₋ₓN (0≤X<1). More specifically, the first nitride semiconductor layer 10 is formed of, for example, undoped GaN. A film thickness of the first nitride semiconductor layer 20 is, for example, 0.5 μm or more to 8 μm or less.

The first nitride semiconductor layer 10 includes a first region 50, a second region 60, and a third region 70 provided between the first region 50 and the second region 60. The first upper surface 12 is provided in the first region 50, the second upper surface 14 is provided in the second region 60, and the third upper surface 16 is provided in the third region. The second upper surface 14 is parallel to the first upper surface 12. For example, the third upper surface 16 is inclined with respect to the first upper surface 12, and is continuously connected to the first upper surface 12 at a boundary between the first region 50 and the third region 70. In addition, for example, the third upper surface 16 is inclined with respect to the second upper surface 14, and is continuously connected to the second upper surface 14 at a boundary between the third region 70 and the second region 60.

The buffer layer 4 is provided between the substrate 2 and the first nitride semiconductor layer 10. The buffer layer 4 has a function of alleviating lattice mismatch between the substrate 2 and the first nitride semiconductor layer 10. The buffer layer 4 has a multilayer structure of, for example, aluminum gallium nitride (Al_{W}Ga_{1-W}N (0<W<1)).

The second nitride semiconductor layer 20 has a bandgap larger than that of the first nitride semiconductor layer 10. Tho second nitride semiconductor layer 20 is formed of, for example, undoped Al_{Y}Ga_{1-Y}N (0<Y≤1 and X<Y). More specifically, the second nitride semiconductor layer 20 is formed of, for example, undoped Al_{0.2}Ga_{0.8}N. A film thickness of the second nitride semiconductor layer 20 is, for example, 15 nm or more to 50 nm or less. In the semiconductor apparatus 100 according to the present embodiment, the second nitride semiconductor layer 20 is provided over the first upper surface 12, the second upper surface 14, and the third upper surface 16. In addition, as described below, the second nitride semiconductor layer 20 is formed at a predetermined film thickness on the first nitride semiconductor layer 10 by, for example, overhang growth.

The second nitride semiconductor layer 20 has the fourth upper surface 22 provided above the first upper surface 12, parallel to the first upper surface, and being a +c face. In addition, the second nitride semiconductor layer 20 has the fifth upper surface 24 provided above the second upper surface 14, parallel to the second upper surface 14, and being a +c face. In addition, the second nitride semiconductor layer 20 has the sixth upper surface 26 provided on the third upper surface 16 and parallel to the third upper surface 16.

The sixth upper surface 26 is inclined at an angle of θ₁ with respect to the fourth upper surface 22, and is continuously connected to, for example, the fourth upper surface 22. In addition, the sixth upper surface 26 is inclined at an angle of θ₂ with respect to the fifth upper surface 24, and is continuously connected to, for example, the fifth upper surface 24.

The gate insulating film 40 is provided over the fourth upper surface 22, the sixth upper surface 26, and the fifth upper surface 24. In other words, the gate insulating film 40 is provided to be in contact with the fourth upper surface 22, the sixth upper surface 26, and the fifth upper surface 24. The gate insulating film 40 is a nitride film formed by, for example, a low temperature chemical vapor deposition (CVD) method or a plasma CVD method.

The source electrode 32 is provided on the fourth upper surface 22. In order to suppress that a good two dimensional electron gas is not generated in the first region 50 due to damage of a nitride semiconductor material at the time of forming the gate insulating film 40, the source electrode 32 has, for example, a portion in direct contact with the fourth upper surface 22 and a portion provided on the gate insulating film 40 on the fourth upper surface 22.

The drain electrode 34 is provided on the fifth upper surface 24. In order to suppress that a good two dimensional electron gas is not generated in the second region 60 due to damage of a nitride semiconductor material at the time of forming the gate insulating film 40, the drain electrode 34 has, for example, a portion in direct contact with the fifth upper surface 24 and a portion provided on the gate insulating film 40 on the fifth upper surface 24.

The gate electrode 36 is provided on the gate insulating film 40 on the sixth upper surface 26. In other words, the gate insulating film 40 is provided between the sixth upper surface 26 and the gate electrode 36. In addition, the gate electrode 36 is provided over a part of the gate insulating film 40 on the fourth upper surface 22 and over a part of the gate insulating film 40 on the fifth upper surface 24. In addition, the gate electrode 36 is provided to be in contact with the gate insulating film 40.

The source electrode 32, the drain electrode 34, and the gate electrode 36 are, for example, metal electrodes. Here, the metal electrode has, for example, a stacked structure of titanium (Ti) and aluminum (Al) or a stacked structure of nickel (Ni) and gold (Au). It is preferable that the first nitride semiconductor layer 10 and the source electrode 32 and the drain electrode 34 are in ohmic contact with each other.

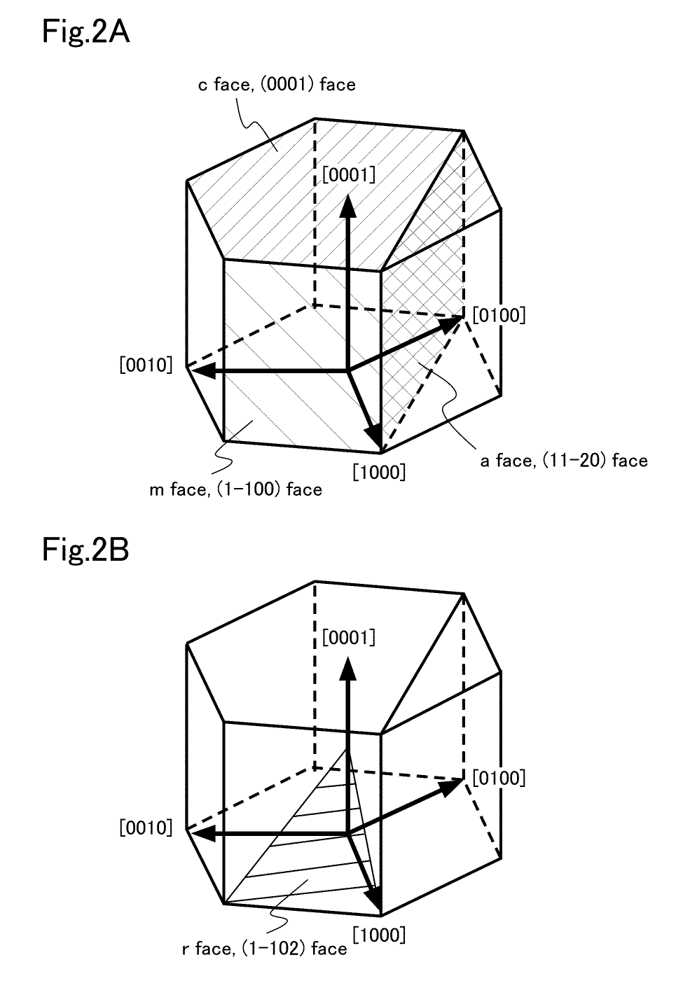

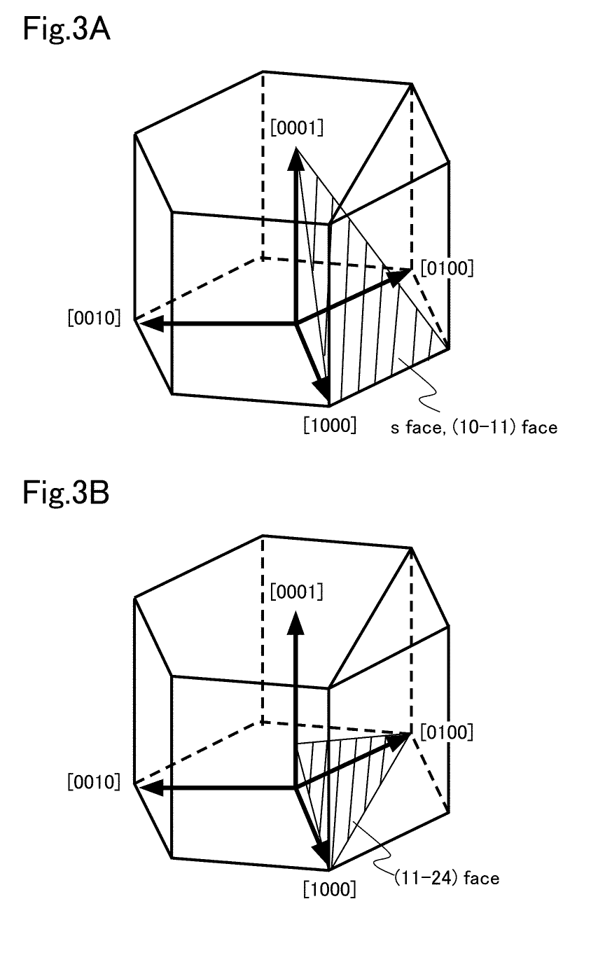

FIGS. 2A and 2B and FIGS. 3A and 3B are schematic diagrams for describing crystal structures and face orientations of a nitride semiconductor according to the present embodiment.

As described above, the sixth upper surface 26 is inclined at the angle of θ₁ with respect to the fourth upper surface 22, and is inclined at the angle of θ₂ with respect to the fifth upper surface 24. It is more preferable that the sixth upper surface 26 is inclined at an angle of 30° or more to 90° or less with respect to the fourth upper surface 22 or the fifth upper surface 24, that is, 30°≤θ₁≤90° or 30°≤θ₂≤90°. A more specific description will be provided with reference to FIGS. 2A and 2B and FIGS. 3A and 3B.

A crystal structure of the nitride semiconductor according to the present embodiment is a hexagonal crystal wurtzite structure. In FIG. 2A, a schematic diagram of a (0001) face, a (1-100) face, and a (11-20) face is shown. The (0001) face is a c face, the (1-100) face is an m face, and the (11-20) face is an a face.

It is preferable that the sixth upper surface 26 is a face perpendicular to the (0001) face. Here, the face perpendicular to the (0001) face includes the (1-100) face and the (11-20) face. In this case, the sixth upper surface 26 is inclined at 90° with respect to the fourth upper surface 22 and the fifth upper surface 24.

In FIG. 2B, a schematic diagram of a (1-102) face is shown. The (1-102) face is an r face. It is preferable that the sixth upper surface 26 is the (1-102) face. In this case, assuming that the second nitride semiconductor layer is formed of GaN, the sixth upper surface 26 is inclined at 43° with respect to the fourth upper surface 22 and the fifth upper surface 24.

In FIG. 3A, a schematic diagram of a (10-11) face is shown. The (10-11) face is an s face. It is preferable that the sixth upper surface 26 is the (10-11) face. In this case, assuming that the second nitride semiconductor layer is formed of GaN, the sixth upper surface 26 is inclined at 62° with respect to the fourth upper surface 22 and the fifth upper surface 24.

In FIG. 3B, a schematic diagram of a (11-24) face is shown. It is preferable that the sixth upper surface 26 is the (11-24) face. In this case, assuming that the second nitride semiconductor layer is formed of GaN, the sixth upper surface 26 is inclined at 39° with respect to the fourth upper surface 22 and the fifth upper surface 24.

It should be noted that in the present specification, displays of face indices are displayed by the Miller indices, and a minus sign “−” in the indices is a sign notated above an index immediately after the minus sign. In other words, for example, the (11-20) face indicates a face such as h=1, k=1, i=−2, and l=0 in a notation such as a (hkil) face using the Miller indices.

It should be noted that even though faces have the same face index, an angle in which the sixth upper surface 26 is inclined with respect to the fourth upper surface 22 and the fifth upper surface 24 is changed due to a change in a lattice constant by a difference in a ratio of Al and Ga, distortion of a crystal structure, and other reasons. Taking such a change into consideration, in the semiconductor apparatus 100 according the present embodiment, when the sixth upper surface 26 is a face perpendicular to the (0001) face, the sixth upper surface 26 is inclined at 88° or more to 90° or less with respect to the fourth upper surface 22 and the fifth upper surface 24. In addition, when the sixth upper surface 26 is the (1-102) face, the sixth upper surface 26 is inclined at 41° or more to 45° or less with respect to the fourth upper surface 22 and the fifth upper surface 24. In addition, when the sixth upper surface 26 is the (10-11) face, the sixth upper surface 26 is inclined at 60° or more to 64° or less with respect to the fourth upper surface 22 and the fifth upper surface 24. In addition, when the sixth upper surface 26 is the (11-24) face, the sixth upper surface 26 is inclined at 37° or more to 41° or less with respect to the fourth upper surface 22 and the fifth upper surface 24.

It is preferable that a gate electrode length of the gate electrode 36 provided so as to be in contact with the sixth upper surface 26 in the gate electrode 36 is at least 1 μm or more.

The angle at which the sixth upper surface 26 is inclined with respect to the fourth upper surface 22 or the fifth upper surface 24 or the gate electrode length of the gate electrode 36 can be evaluated by evaluating a photograph of a cross section of the semiconductor apparatus 100 captured by, for example, a transmission electron microscope (TEM) or a scanning electron microscope (SEM).

For example, unlike a case where the angle θ₁ is equal to or less than 89°, in a case where the angle θ₁ is 90°, a case where a part of the sixth upper surface 26 is positioned laterally to the third upper surface 16 or a case where a part of the gate electrode 36 is positioned laterally to the sixth upper surface 26 can occur. In the present specification, it is considered that “the sixth upper surface 26 is provided on the third upper surface 16” and 37 the gate electrode 36 is provided on the sixth upper surface 26”, including this case.

It is preferable that the sixth upper surface 26 further has a part of a −c face. In this case, it is preferable that the first nitride semiconductor layer 10 or the second nitride semiconductor layer 20 between the sixth upper surface 26 and the substrate 2 has nitride semiconductor layers such as AlN layers or GaN layers (not shown), as an appropriate example, about several atomic layers. In addition, for example, magnesium (Mg) may be contained in the first nitride semiconductor layer 10 or the second nitride semiconductor layer 20 between the sixth upper surface 26 and the substrate 2.

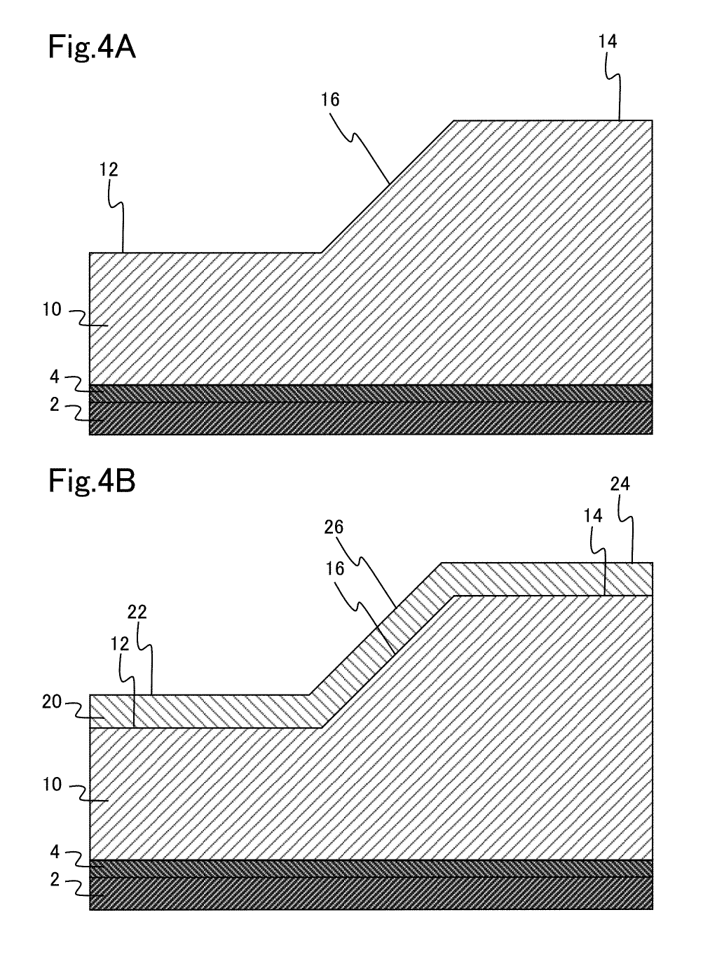

FIGS. 4A and 4B are schematic cross-sectional views showing some of manufacturing processes in a manufacturing method of the semiconductor apparatus 100 according to the present embodiment.

The manufacturing method of the semiconductor apparatus according to the present embodiment includes: forming a first nitride semiconductor layer on a substrate, the first nitride semiconductor layer being provided over a first region, a second region, and a third region between the first region and the second region and the first nitride semiconductor layer having a first upper surface (a second upper surface); forming a second upper surface (a first upper surface) in the first region by removing a part of the first nitride semiconductor layer of the first region, the second upper surface (the first upper surface) being parallel to the first upper surface (the second upper surface); forming a third upper surface in the third region by removing a part of the first nitride semiconductor layer of the third region, the third upper surface being inclined with respect to the first upper surface or the second upper surface; forming a second nitride semiconductor layer having a fourth upper surface provided above the second upper surface (the first upper surface), a fifth upper surface provided above the first upper surface (the second upper surface) and a sixth upper surface provided above the third upper surface, the fourth upper surface being parallel to the second upper surface (the first upper surface) and being a +c face, the fifth upper surface being parallel to the first upper surface (the second upper surface) and being a +c face, the sixth upper surface being parallel to the third upper surface and the second nitride semiconductor layer having a bandgap larger than that of the first nitride semiconductor layer; forming a source electrode on the fourth upper surface; forming a drain electrode on the fifth upper surface; forming a gate insulating film on tho sixth upper surface; and forming a gate electrode on the gate insulating film.

First, the buffer layer 4 and the first nitride semiconductor layer 10 formed of, for example, GaN and having the second upper surface 14 are sequentially formed on the substrate 2 by, for example, a metal organic chemical vapor deposition (MOCVD) method.

Then, as shown in FIG. 4A, the first upper surface 12 parallel to the second upper surface 14 is formed in the first region 50 by removing a part of the first nitride semiconductor layer 10 by a dry etching method such as a reactive ion etching (RIE) method. In addition, the third upper surface 16 inclined with respect to the first upper surface 12 and the second upper surface 14 formed in the third region 70.

As the second upper surface 14, a surface formed by an MOCVD method may be used as it is. Alternatively, a surface formed by, for example, an MOCVD method may be processed by an RIE method and be then used as the second upper surface 14.

Then, as shown in FIG. 4B, the second nitride semiconductor layer 20 formed of, for example, AlGaN is formed on the first upper surface 12, the second upper surface 14, and the third upper surface 16 by overhang growth. Here, the second nitride semiconductor layer 20 has the fourth upper surface 22 provided above the first upper surface 12, parallel to the first upper surface 12, and being the +c face, the fifth upper surface 24 provided above the second upper surface 14, parallel to the second upper surface 14, and being the +c face, and the sixth upper surface 26 provided above the third upper surface 16 and parallel to the third upper surface 16.

Then, the source electrode is formed on the fourth upper surface 22, the drain electrode is formed the fifth upper surface 24, the gate insulating film is formed on the sixth upper surface 26, and the gate electrode is formed on the gate insulating film to obtain the semiconductor apparatus according to the present embodiment.

In a case of manufacturing the semiconductor apparatus 100 in which the sixth upper surface 26 has a part of the −c face, when the first nitride semiconductor layer 10 or the second nitride semiconductor layer 20 is formed, the AlN layers or the GaN layers (not shown), as an appropriate example, about several atomic layers may be inserted into the third region 70. Alternatively, when the first nitride semiconductor layer 10 or the second nitride semiconductor layer 20 is formed, for example, magnesium (Mg) may be appropriately contained in the first nitride semiconductor layer 10 or the second nitride semiconductor layer 20 of the third region 70.

Next, a function and an effect of the semiconductor apparatus 100 according to the present embodiment will be described.

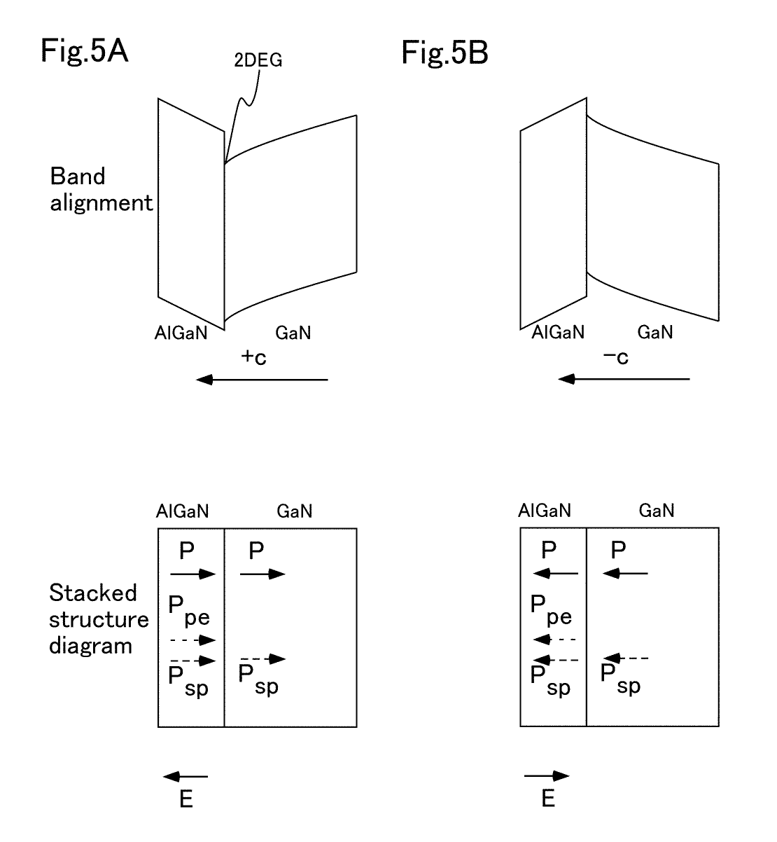

FIGS. 5A and 5B are schematic diagrams showing a band structure formed by the first nitride semiconductor layer 10 and the second nitride semiconductor layer 20 in a description of a function and an effect of the semiconductor apparatus 100 according to the present embodiment.

FIG. 5A is a schematic diagram showing a band structure in a nitride semiconductor material having a stacked structure of a GaN layer and an AlGaN layer and having an upper surface being a +c face.

Within the nitride semiconductor material, spontaneous polarization Pₛₚ caused by asymmetry of a wurtzite type crystal structure appears in a c-axis direction. Further, for example, when the first nitride semiconductor layer 10 is formed of GaN and the second nitride semiconductor layer 20 is formed of AlGaN as shown in FIG. 5A, a lattice constant of an a axis of AlGaN is smaller than that of an a axis of GaN, and elongation strain is thus applied to the second nitride semiconductor layer 20. Piezoelectric polarization Pₚₑ resulting from this elongation strain appears in the same direction as that of the spontaneous polarization Pₛₚ described above, in the second nitride semiconductor layer 20. Due to a combination of the spontaneous polarization Pₛₚ and the piezoelectric polarization Pₚₑ, bending as shown in FIG. 5A is generated in the band structure, and a two dimensional electron gas (2DEG) is generated on an interface between the first nitride semiconductor layer 10 and the second nitride semiconductor layer 20.

As described above, in the semiconductor apparatus using the nitride semiconductor material, high conductivity can be obtained by the 2DEG generated by controlling the spontaneous polarization and the piezoelectric polarization, but it has been a problem that it is difficult to form a normally-off transistor.

In the semiconductor apparatus 100 according to the present embodiment, the fourth upper surface 22 is the +c face and the fifth upper surface 24 is the +c face. Since the sixth upper surface 26 is parallel to the third upper surface 16, the sixth upper surface 26 is inclined with respect to the fourth upper surface 22 and the fifth upper surface. Since the +c face is a face in which the piezoelectric polarization is strong, an amount of generated 2DEG is large. On the other hand, in a face inclined from the +c face, the piezoelectric polarization is smaller than in the +c face, and an amount of generated 2DEG is thus reduced. Therefore, the source electrode 32 and the drain electrode 34 are disposed on the +c face in which the amount of 2DEG is large. On the other hand, in a region in which the gate electrode is disposed, an amount of generated 2DEG is suppressed using the face inclined from the +c face. In this way, the semiconductor apparatus 100 performing a normally-off operation can be provided.

In addition, generally, processing of a nitride semiconductor layer is difficult since proccessability or film formation selectivity is poor. However, the third upper surface 16 and the sixth upper surface 26 can be formed by a combination of a dry etching method having good proccessability and an overhang growth method, as described above. For this reason, it is possible to provide the semiconductor apparatus 100 performing a normally-off operation without performing fine processing control or doping.

It is more preferable that the sixth upper surface 26 is inclined at an angle of 30° or more to 90° or less with respect to the fourth upper surface 22 or the fifth upper surface 24 in order to suppress the piezoelectric polarization and perform the normally-off operation. Alternatively, it is preferable that the sixth upper surface 26 is inclined at 88° or more to 90° or less, 41° or more to 45° or less, 60° or more to 64° or less, or 37° or more to 41° or less with respect to the fourth upper surface 22 or the fifth upper surface 24 or a face orientation of the sixth upper surface 26 is the face perpendicular to the (0001) face, the (1-102) face, the (10-11) face, or the (11-24) face. In particular, the piezoelectric polarization is suppressed strongly in the face perpendicular to the (0001) face and the face (11-24).

FIG. 5B is a schematic diagram showing a band structure in a nitride semiconductor material having a stacked structure of a GaN layer and an AlGaN layer and having an upper surface being a −c face. In this case, direction of an electric field generated in the nitride semiconductor material due to polarization is opposite to that in a case of FIG. 4A. For this reason, a 2DEG is not generated. For this reason, the sixth upper surface 26 further has a part of the −c face, such that the semiconductor apparatus 100 performing the normally-off operation is more easily provided.

When the gate electrode length of the gate electrode 36 provided so as to be in contact with the sixth upper surface 26 in the gate electrode 36 is 1 μm or more, a gate provided in a portion in which an amount of generated 2DEG is small becomes sufficiently long. For this reason, further, it is possible to provide the semiconductor apparatus 100 easily performing a normally-off operation without performing fine processing control or doping.

According to the semiconductor apparatus 100 according to the present embodiment, it is possible to provide the semiconductor apparatus performing the normally-off operation.

### Second Embodiment

In a semiconductor apparatus 110 according the present embodiment, a sixth upper surface 26 is inclined at 90° with respect to a fourth upper surface 22 or a fifth upper surface 24, in the first embodiment. In other words, the semiconductor apparatus 110 according to the present embodiment is a semiconductor apparatus in which the sixth upper surface 26 is a face perpendicular to a (0001) face. For example, the sixth upper surface 26 is a (10-10) face or a (11-20) face. Here, a description for contents overlapping those of the first embodiment is omitted.

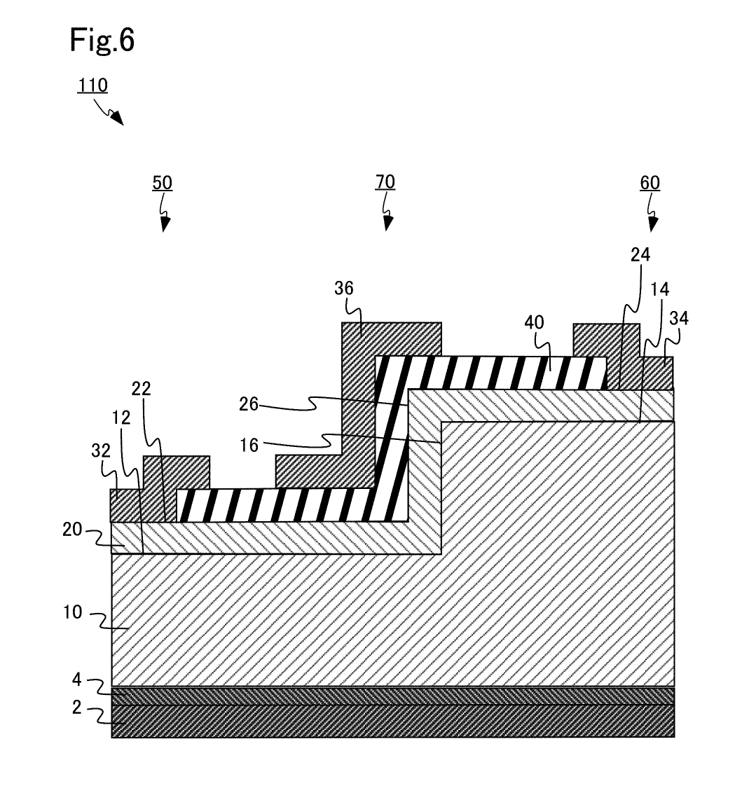

FIG. 6 is a schematic cross-sectional view of the semiconductor apparatus 110 according to the present embodiment.

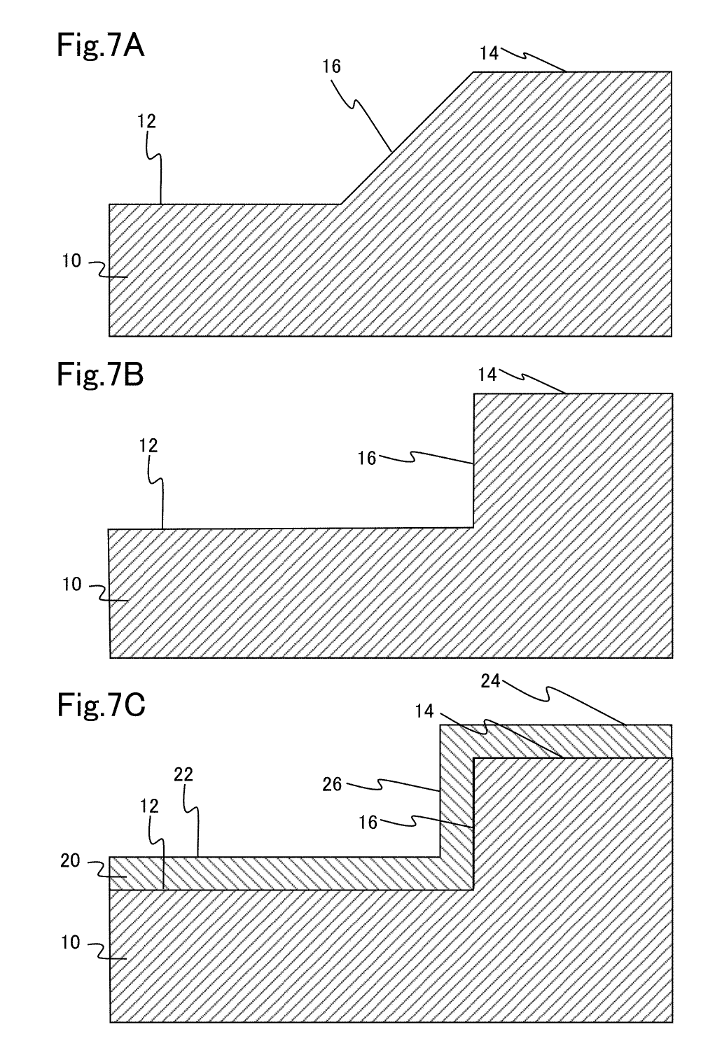

FIGS. 7A to 7C are schematic cross-sectional views showing some of manufacturing processes in a manufacturing method of the semiconductor apparatus 110 according to the present embodiment. It should be noted that descriptions of FIGS. 7A and 7C are the same as those of FIGS. 4A and 4B, respectively, and are thus omitted. In addition, a substrate 2 and a buffer layer 4 are omitted in FIGS. 7A to 7C.

In FIG. 7B, a third upper surface 16 is processed by a wet etching method using, for example, hot phosphoric acid. In this way, the third upper surface 16 can be formed as the face perpendicular to the (0001) face, such as the (10-10) face or the (11-20) face.

According to the semiconductor apparatus 110 according to the present embodiment, it is possible to provide the semiconductor apparatus performing a normally-off operation.

### Third Embodiment

A semiconductor apparatus 120 according to the present embodiment is different from the semiconductor apparatus according to the first embodiment and the semiconductor apparatus according to the second embodiment in that a recess 80 is provided in a third region 70 of a first nitride semiconductor layer 10. Here, a description for contents overlapping those of the first embodiment and second embodiment is omitted.

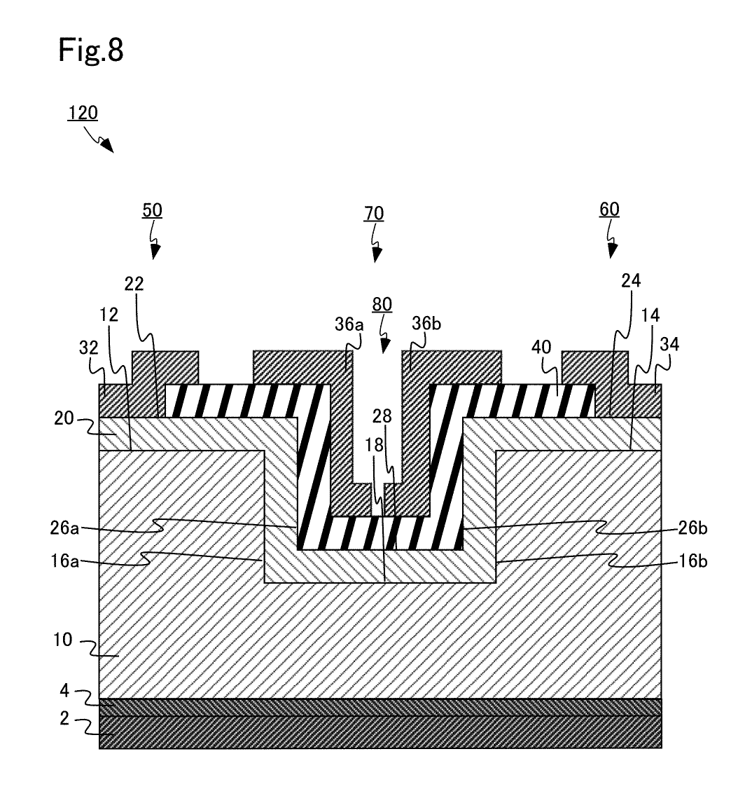

FIG. 8 is a schematic cross-sectional view of the semiconductor apparatus 120 according to the present embodiment.

In the semiconductor apparatus 120, the recess 80 is provided. A plurality of third upper surfaces 16a and 16b are provided on the first nitride semiconductor layer 10 on side surfaces of the recess 80. A plurality of sixth upper surfaces 26a and 26b are provided on a second nitride semiconductor layer 20 on side surfaces of the recess 80. The third upper surfaces 16a and the sixth upper surface 26a are parallel to each other. In addition, the third upper surfaces 16b and the sixth upper surface 26b are parallel to each other. The third upper surface 16a, the sixth upper surface 26a, the third upper surface 16b, and the sixth upper surface 26b are for example, faces perpendicular to a (0001) face in which generation of a 2DEG is suppressed. The third upper surface 16a, the sixth upper surface 26a, the third upper surface 16b, and the sixth upper surface 26b may be (1-102) faces, (10-11) faces, or (11-24) faces.

In addition, a seventh upper surface 18 is provided on the first nitride semiconductor layer 10 on a lower surface of the recess 80. An eighth upper surface 28 is provided on the second nitride semiconductor layer 20 on the lower surface of the recess 80. The seventh upper surface 18 and the eighth upper surface 28 are, for example, +c faces in which an amount of generated 2DEG is large.

It should be noted that the number of recesses 80 in FIG. 8 is one, but the number of recesses 80 is not limited to that shown in FIG. 8.

A gate electrode 36a and a gate electrode 36b are provided above the sixth upper surfaces 26a and 26b, respectively, to form a double gate structure. The gate electrode 36a is provided over a fourth upper surface 22 and the eighth upper surface 28. In addition, the gate electrode 36b is provided over a fifth upper surface 24 and the eighth upper surface 28.

According to the semiconductor apparatus 120 according to the present embodiment, even though transistors have the same size, a gate length can be gained using the side surfaces of the recess 80. In this way, a normally-off transistor can be more easily manufactured.

According to the double gate structure, a gate length can be doubled even at the same depth of the recess 80. If the recess 80 is excessively deep, when the semiconductor apparatus 120 is manufactured, a manner of introducing a raw material gas, an etching gas, or the like, into the recess 80 becomes worse, such that good characteristics can not be obtained. Therefore, it is preferable to use a structure capable of obtaining a long gate length even if the recess 80 has the same depth, as the double gate structure.

### Fourth Embodiment

A semiconductor apparatus 130 according to the present embodiment is different from the semiconductor apparatus according to the first embodiment and the semiconductor apparatus according to the second embodiment in that protrusions 90 are provided in a third region 70 of a first nitride semiconductor layer 10. Here, a description for contents overlapping those of the first to third embodiments omitted.

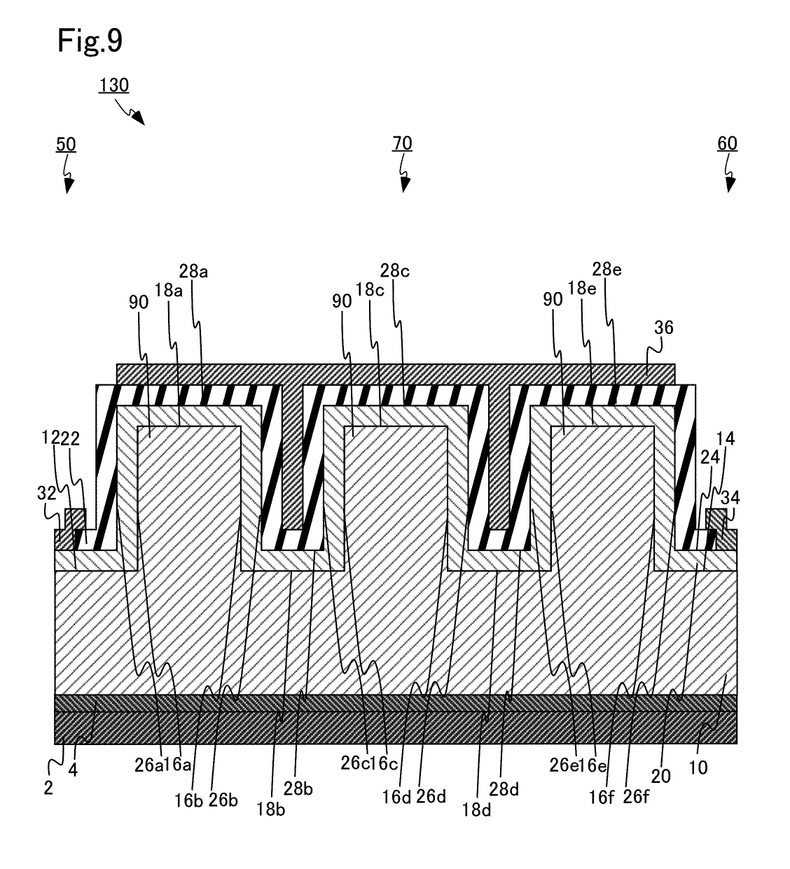

FIG. 9 is a schematic cross-sectional view of the semiconductor apparatus 130 according to the present embodiment.

A plurality of protrusions 90a, 90b, and 90c are provided in the third region 70. Third upper surfaces 16a, 16b, 16c, 16d, 16e, and 16f are provided on a first nitride semiconductor layer 10, which are side surfaces of the protrusions 90a, 90b, and 90c. In addition, sixth upper surfaces 26a, 26b, 26c, 26d, 26e, and 26f are provided on a second nitride semiconductor layer 20, which are side surfaces of the protrusions 90a, 90b, and 90c. The third upper surfaces 16a, 16b, 16c, 16d, 16e, and 16f and the sixth upper surfaces 26a, 26b, 26c, 26d, 26e, and 26f are, for example, faces perpendicular to a (0001) face in which generation of a 2DEG is suppressed. The third upper surfaces 16a, 16b, 16c, 16d, 16e, and 16f and the sixth upper surfaces 26a, 26b, 26c, 26d, 26e, and 26f may be (1-102) faces, (10-11) faces, or (11-24) faces.

Seventh upper surfaces 18b and 18d are provided on the first nitride semiconductor layer 10 on lower surfaces between the protrusions 90. In addition, eighth upper surfaces 28b and 28d are provided on the second nitride semiconductor layer 20 on the lower surfaces between the protrusions 90. In addition, seventh upper surfaces 18a, 18c, and 18e are provided on the first nitride semiconductor layer 10 on upper surfaces of the protrusions 90. In addition, eighth upper surfaces 28a, 28c, and 28e are provided on the second nitride semiconductor layer 20 on the upper surfaces of the protrusions 90. The seventh upper surfaces 18a, 18b, 18c, 18d, and 18e and the eighth upper surfaces 28a, 28b, 28c, 28d, and 28e are, for example, +c faces in which an amount of generated 2DEG is large.

It should be noted that the number of protrusions 90 in FIG. 9 is three, but the number of protrusions 90 is not limited to that shown in FIG. 9.

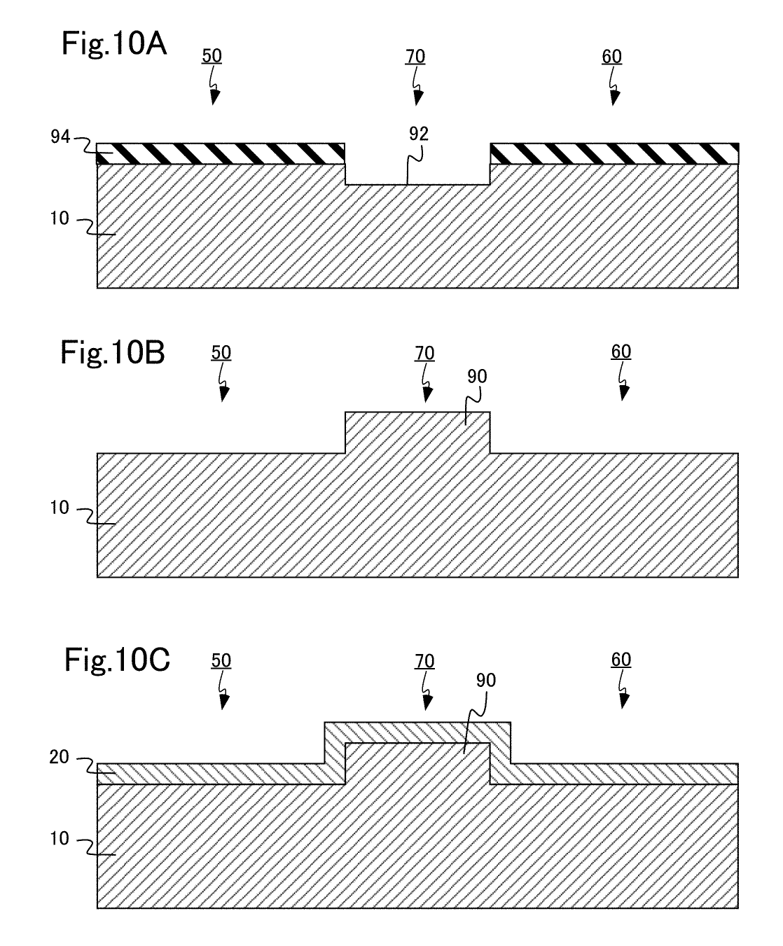

FIGS. 10A to 10C are schematic cross-sectional views showing some of manufacturing processes in a manufacturing method of the semiconductor apparatus 130 according to the present embodiment. FIGS. 10A to 10C are schematic cross-sectional views showing some of manufacturing processes of the protrusion 90. It should be noted that a substrate 2 and a buffer layer 4 are omitted in FIGS. 10A to 10C.

After the buffer layer 4, a first nitride semiconductor layer 10, and a resist 94 are sequentially formed on the substrate 2, a trench 92 is formed on the first nitride semiconductor layer 10 using the resist 94 as a mask, as shown in FIG. 10A.

Then, for example, a nitride semiconductor material having the same composition as that of a first nitride semiconductor material is formed in the trench 92 to form the protrusion 90. Then, the resist 94 is removed (see FIG. 10B). It should be noted that protrusion 90 becomes, for example, a part of the first nitride semiconductor layer 10 after being formed.

Then, the second nitride semiconductor layer 20 is overhang-grown on the first nitride semiconductor layer 10 and the protrusion 90 (see FIG. 10C). In this case, the faces perpendicular to the (0001) face, for example, the (10-10) faces or the (11-20) faces are easily formed on side surfaces of the protrusion 90, which is preferable.

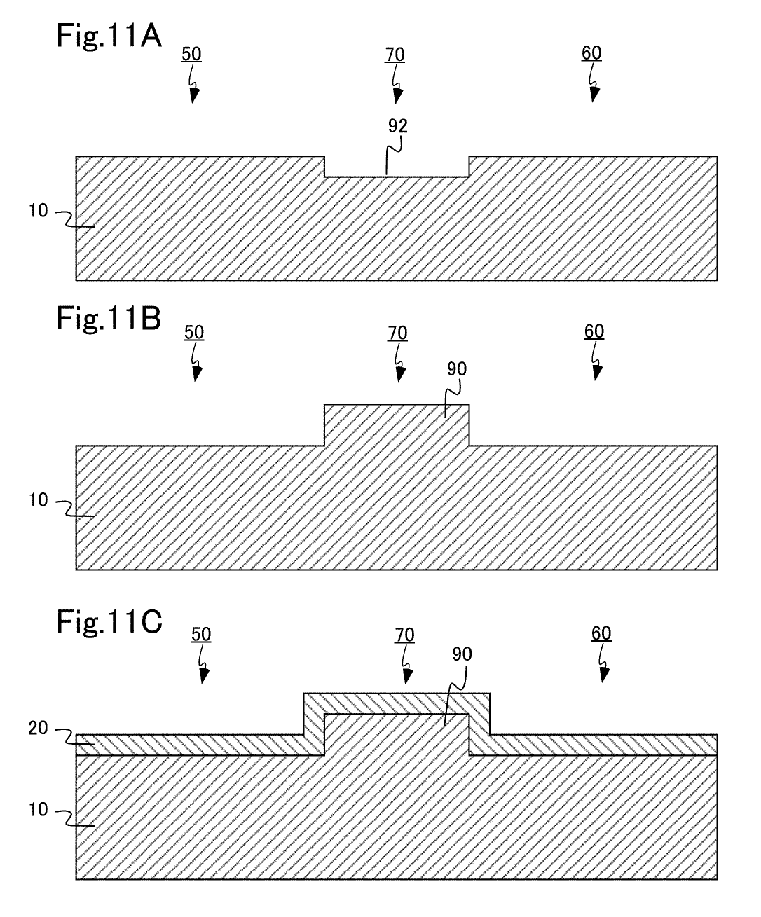

FIGS. 11A to 11C are schematic cross-sectional views showing some of manufacturing processes in a modified example of a manufacturing method of the semiconductor apparatus 130 according to the present embodiment. FIGS. 11A to 11C are schematic cross-sectional views showing some of manufacturing processes of the protrusion 90. It should be noted that a substrate 2 and a buffer layer 4 are omitted in FIGS. 11A to 11C. In this case, a trench 92 is formed on the first nitride semiconductor layer 10 by, for example, a dry etching method (see FIG. 11A), and a protrusion 90 becoming a part of the first nitride semiconductor layer 10 is formed in the trench 92 (see FIG. 11B). It is possible to form the protrusion 90 by controlling the supply of ammonia, trimethyl indium (TMI), trimethyl gallium (TMG), or trimethyl aluminum (TMA), which is a raw material, to the trench 92.

According to the semiconductor apparatus 130 according to the present embodiment, it is possible to provide the semiconductor apparatus performing a normally-off operation.

### Fifth Embodiment

In a semiconductor apparatus 140 according to the present embodiment, a third upper surface 16 and a sixth upper surface 26 are (1-102) faces, (10-11) faces, or (11-24) faces. Here, a description for contents overlapping those of the first to fourth embodiments is omitted.

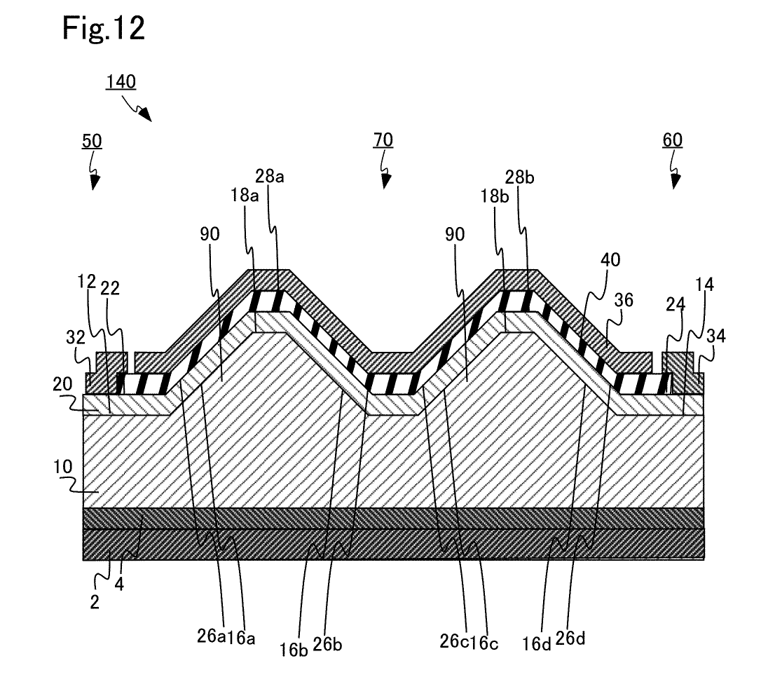

FIG. 12 is a schematic cross-sectional view of the semiconductor apparatus 140 according to the present embodiment.

According to the semiconductor apparatus 140 according to the present embodiment, it is possible to provide the semiconductor apparatus performing a normally-off operation.

### Sixth Embodiment

A semiconductor apparatus 150 according to the present embodiment is different from the semiconductor apparatuses according to the first to fifth embodiments in that a second nitride semiconductor layer 20 is not provided in a third region 70. Here, a description for contents overlapping those of the first to fifth embodiments is omitted.

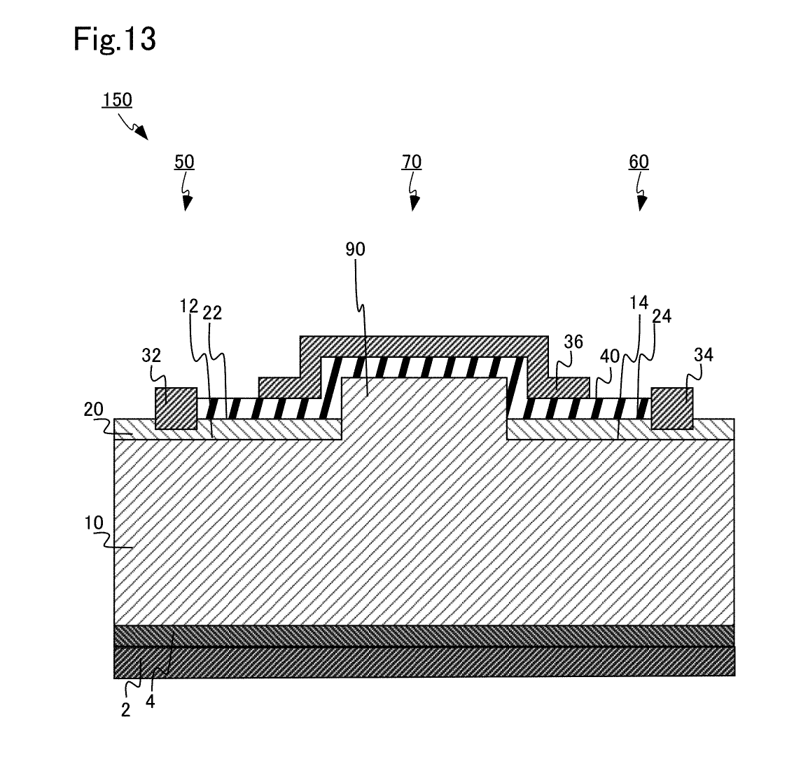

FIG. 13 is a schematic cross-sectional view of the semiconductor apparatus 150 according to the present embodiment. A protrusion 90 is provided in the third region 70, but the second nitride semiconductor layer 20 is not provided in the third region 70.

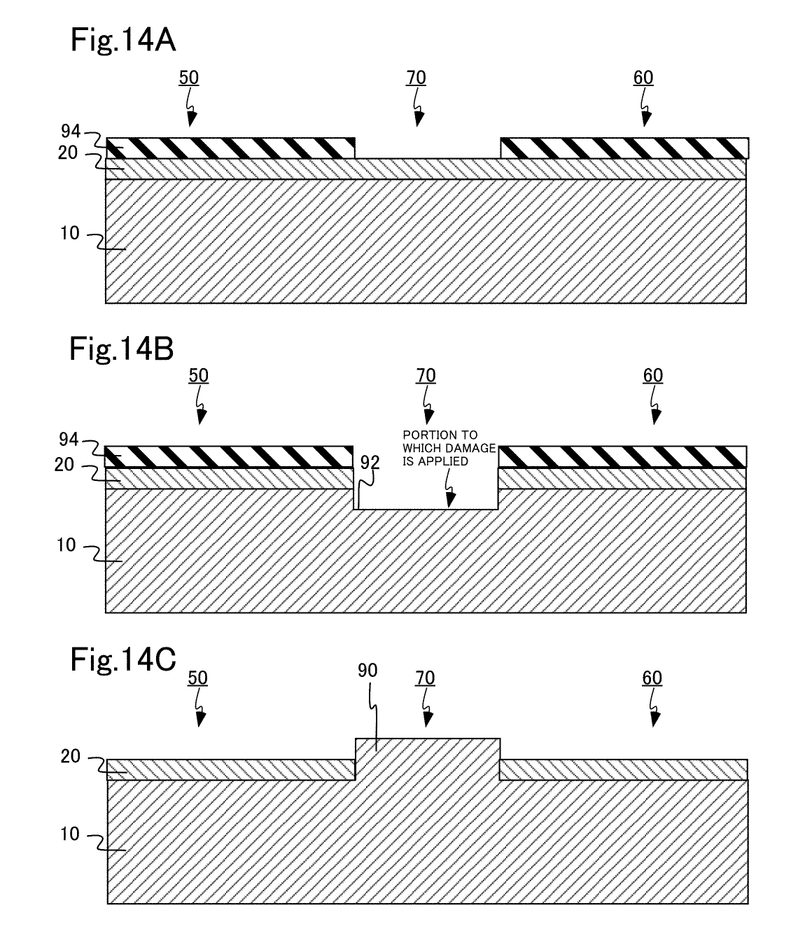

FIGS. 14A to 14C are schematic cross-sectional views showing some of manufacturing processes in a manufacturing method of the semiconductor apparatus 150 according to the present embodiment. It should be noted that a substrate 2 and a buffer layer 4 are omitted in FIGS. 14A to 14C.

First, the buffer layer 4, a first nitride semiconductor layer 10, and the second nitride semiconductor layer 20 are sequentially formed on the substrate 2. Then, a resist 94 is formed on the second nitride semiconductor layer 20. Then, a part of the resist 94 of the third region 70 is removed to expose the second nitride semiconductor layer 20 (see FIG. 14A), and a trench 92 penetrating through the second nitride semiconductor layer 20 and arriving at the first nitride semiconductor layer 10 is formed by, for example, a dry etching method using the resist 94 as a mask (see FIG. 14B). For example, a nitride semiconductor material having the same composition as that of the first nitride semiconductor layer 10 is selectively grown in the trench 92 to form the protrusion 90 becoming a part of the first nitride semiconductor layer 10 (see FIG. 14C). Then, the resist 94 is removed, and a gate insulating film 40, a source electrode 32, a drain electrode 34, and a gate electrode 36 are formed to obtain the semiconductor apparatus 150 according to the present embodiment.

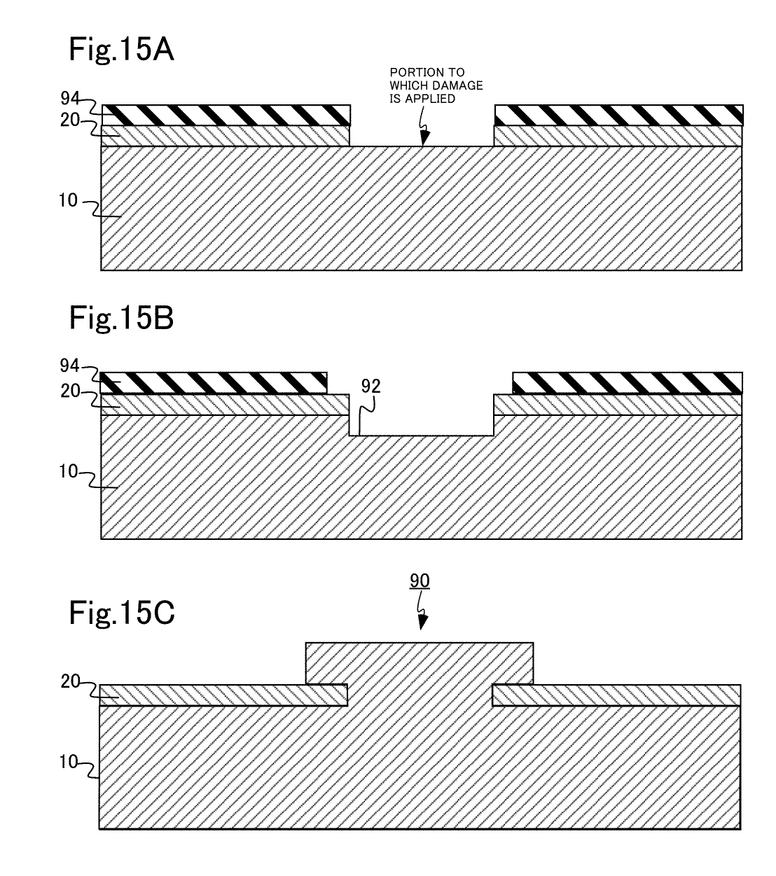

FIGS. 15A to 15C are schematic cross-sectional views showing some of manufacturing processes in a modified example of a manufacturing method of the semiconductor apparatus 150 according to the present embodiment. It should be noted that a substrate 2 and a buffer layer 4 are omitted in FIGS. 15A to 15C.

A part of a resist 94 of a third region 70 and a part of a second nitride semiconductor layer 20 are removed to expose a first nitride semiconductor layer 10 (see FIG. 15A), and a thermal decomposition process is then performed under a hydrogen atmosphere to form a trench 92 in the first nitride semiconductor layer 10 (FIG. 15B). Then, a part of the first nitride semiconductor layer 10 is selectively grown in the trench 92 to form a protrusion 90 becoming a part of the first nitride semiconductor layer 10. Then, the resist 94 is removed, and a gate insulating film 40, a source electrode 32, a drain electrode 34, and a gate electrode 36 are formed to obtain the semiconductor apparatus 150 according to the present embodiment.

In the semiconductor apparatus 150 according to the present embodiment, the second nitride semiconductor layer 20 is not provided in the third region 70, and thus, a 2DEG is not formed. Therefore, a normally-off transistor is easily manufactured. In addition, a face inclined with respect to a fourth upper surface 22 or a fifth upper surface 24, such as a face perpendicular to a (0001) face is easily formed by selectively growing a part of the first nitride semiconductor layer. Further, the bottom of the trench 92 can be positioned on a level below the vicinity of an interface between the first nitride semiconductor layer 10 and the second nitride semiconductor layer 20 on which a 2DEG is formed and conduction is made. Since damage is applied to the bottom of the trench 92 by a dry etching method, or the like, good electric conduction characteristics can not be obtained, but according to the semiconductor apparatus 150 according to the present embodiment, it is possible to operate the semiconductor apparatus 150 while avoiding a part to which the damage is applied.

According to the semiconductor apparatus 150 according to the present embodiment, it is possible to provide the semiconductor apparatus performing a normally-off operation.

### Seventh Embodiment

A semiconductor apparatus 160 according to the present embodiment is different from the semiconductor apparatuses according to the first to sixth embodiments in that it further includes a p-type third nitride semiconductor layer 96 provided between a sixth upper surface 26 and a gate electrode 36. Here, a description for contents overlapping those of the first to sixth embodiments is omitted.

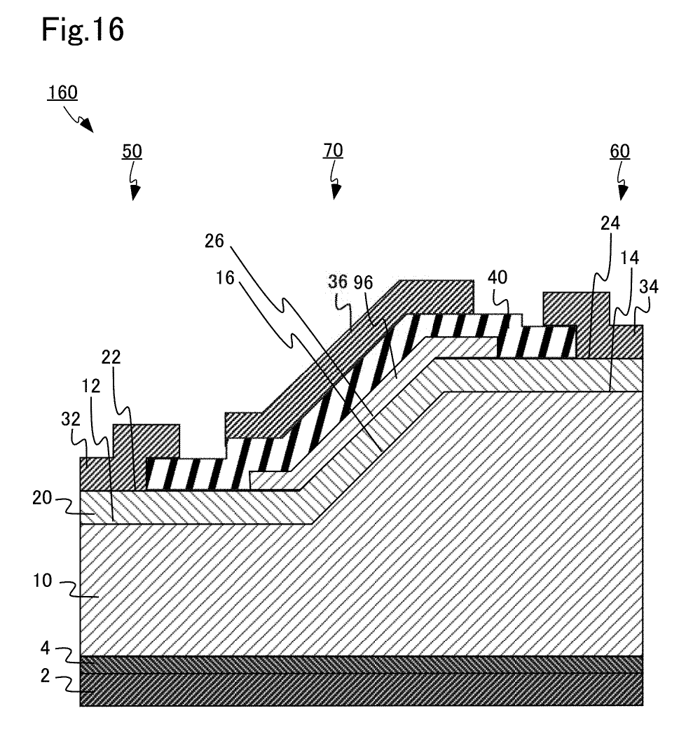

FIG. 16 is a schematic cross-sectional view of the semiconductor apparatus 160 according to the present embodiment.

It is possible to provide the semiconductor apparatus performing a normally-off operation by providing the p-type third nitride semiconductor layer 96 and forming a pn-junction between the p-type third nitride semiconductor layer 96 and a first nitride semiconductor layer 10 or a second nitride semiconductor layer 20.

While certain embodiments have been described, these embodiments have been presented by way of example only, and are not intended to limit the scope of the inventions. Indeed, the semiconductor apparatus and the manufacturing method thereof described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor apparatus comprising:
a first nitride semiconductor layer including a first region having a first upper surface, a second region having a second upper surface parallel to the first upper surface, and a third region provided between the first region and the second region and having a third upper surface inclined with respect to the first upper surface and the second upper surface;
a second nitride semiconductor layer including a fourth upper surface provided above the first upper surface, a fifth upper surface provided above the second upper surface, and a sixth upper surface provided above the third upper surface and being parallel to the third upper surface, the fourth upper surface being parallel to the first upper surface and being a +c face, the fifth upper surface parallel to the second upper surface and being a +c face, and the second nitride semiconductor having a bandgap larger than that of the first nitride semiconductor layer;
a source electrode provided on the fourth upper surface;
a drain electrode provided on the fifth upper surface;
a gate electrode provided on the sixth upper surface; and
a gate insulating film provided between the sixth upper surface and the gate electrode.

2. The semiconductor apparatus according to claim 1, wherein the sixth upper surface is inclined at 30° or more to 90° or less with respect to the fourth upper surface or the fifth upper surface.

3. The semiconductor apparatus according to claim 2, wherein the sixth upper surface is inclined at 88° or more to 90° or less, 41° or more to 45° or less, 60° or more to 64° or less, or 37° or more to 41° or less with respect to the fourth upper surface or the fifth upper surface.

4. The semiconductor apparatus according to claim 1, wherein the sixth upper surface is a face perpendicular to a (0001) face, a (1-102) face, a (10-11) face, or a (11-24) face.

5. The semiconductor apparatus according to claim 1, wherein the third region has a protrusion or a recess, and the sixth upper surface is a face parallel to a side surface of the protrusion or the recess.

6. The semiconductor apparatus according to claim 1, wherein the second nitride semiconductor layer is provided over the first upper surface, the second upper surface, and the third upper surface.

7. The semiconductor apparatus according to claim 1, wherein a gate electrode length of the gate electrode provided to be in contact with the sixth upper surface in the gate electrode is at least 1 μm or more.

8. The semiconductor apparatus according to claim 1, wherein the sixth upper surface further has a part of a −c face.

9. The semiconductor apparatus according to claim 1, further comprising a p-type third nitride semiconductor layer provided between the sixth upper surface and the gate electrode.

10. A semiconductor apparatus comprising:
a first nitride semiconductor layer including a first region having a first upper surface, a second region having a second upper surface parallel to the first upper surface, and a third region provided between the first region and the second region and having a third upper surface inclined at an angle of 88° to 90° with respect to the first upper surface or the second upper surface;
a second nitride semiconductor layer provided on the first nitride semiconductor layer, the second nitride semiconductor including a fourth upper surface provided above the first upper surface, a fifth upper surface provided above the second upper surface and a sixth upper surface parallel to the third upper surface, the fourth upper surface being parallel to the first upper surface and being a +c face, the fifth upper surface being parallel to the second upper surface and being a +c face and the second nitride semiconductor layer having a bandgap larger than that of the first nitride semiconductor layer;
a source electrode provided on the fourth upper surface;
a drain electrode provided on the fifth upper surface;
a gate insulating film provided to be in contact with the sixth upper surface; and
a gate electrode provided to be in contact with the gate insulating film.

11. A manufacturing method of a semiconductor apparatus, comprising:
forming a first nitride semiconductor layer on a substrate, the first nitride semiconductor layer being provided over a first region, a second region, and a third region between the first region and the second region and the first nitride semiconductor layer having a first upper surface;
forming a second upper surface in the first region by removing a part of the first nitride semiconductor layer of the first region, the second upper surface being parallel to the first upper surface;
forming a third upper surface in the third region by removing a part of the first nitride semiconductor layer of the third region, the third upper surface being inclined with respect to the first upper surface or the second upper surface;
forming a second nitride semiconductor layer having a fourth upper surface provided above the second upper surface, a fifth upper surface provided above the first upper surface and a sixth upper surface provided above the third upper surface, the fourth upper surface being parallel to the second upper surface and being a +c face, the fifth upper surface being parallel to the first upper surface and being a +c face, the sixth upper surface being parallel to the third upper surface and the second nitride semiconductor layer having a bandgap larger than that of the first nitride semiconductor layer;
forming a source electrode on the fourth upper surface;
forming a drain electrode on the fifth upper surface;
forming a gate insulating film on the sixth upper surface; and
forming a gate electrode on the gate insulating film.

12. The manufacturing method of a semiconductor apparatus according to claim 11, wherein the sixth upper surface is inclined at 30° or more to 90° or less with respect to the fourth upper surface or the fifth upper surface.

13. The manufacturing method of a semiconductor apparatus according to claim 12, wherein the sixth upper surface is inclined at 88° or more to 90° or less, 41° or more to 45° or less, 60° or more to 64° or less, or 37° or more to 41° or less with respect to the fourth upper surface or the fifth upper surface.

14. The manufacturing method of a semiconductor apparatus according to claim 11, wherein the sixth upper surface is a face perpendicular to a (0001) face, a (1-102) face, a (10-11) face, or a (11-24) face.

15. The manufacturing method of a semiconductor apparatus according to claim 11, wherein the parts of the first nitride semiconductor layer of the first region and the third region are removed by a dry etching method, and
the part of the first nitride semiconductor layer of the third region is removed by a wet etching method.
